(19) United States
(12) Patent Application Publication
(10) Pub. No.: US 2026/0050045 A1
(43) Pub. Date: Feb. 19, 2026

(54) Apparatus And Method Of Determining Battery Internal Resistance In A Battery Power Supply Circuit

(71) Applicant: Xsense Ltd., Migdal Tefen (IL)

(72) Inventor: Andrii Isachenkov, Migdal Tefen (IL)

(21) Appl. No.: 18/803,718

(22) Filed: Aug. 13, 2024

(51) Int. Cl. G01R 31/389; G01R 31/3842

(52) U.S. Cl. CPC G01R 31/389; G01R 31/3842

(57) ABSTRACT

A novel and useful apparatus and method of determining battery internal resistance for use in a battery power supply (BPS) circuit such as used in a data logger. The mechanism periodically determines the internal resistance of a battery connected to the BPS circuit while requiring minimal to no extra hardware and minimal compute requirements. Battery voltage and the voltage across a capacitor tank are periodically measured before and after a current charging surge and used to calculate battery internal resistance using a dual current surge technique. The BPS includes a voltage converter connected to a battery for generating a voltage greater or less than the battery voltage, a current limiter configured to limit current in a current limiting mode and to provide a shunt in a noncurrent limiting mode, a capacitor tank for providing an output voltage to the load. A relaxation/stabilization period is then applied before the load is enabled to maximize battery life.

### FIELD OF THE INVENTION

The present disclosure relates to an apparatus and method of determining battery internal resistance for use in a battery power supply circuit.

### BACKGROUND OF THE INVENTION

Many different types of electronic devices may impose particular demands on their power supplies. Lithium and lithium-ion batteries are frequently used in the power supplies of these devices. Traditional lithium-chemistry based batteries generally have a flat discharge curve and very low internal resistance. This makes them advantageous for use in applications with relatively high power requirements, such as in cellular modems, RF transceivers, IoT (Internet of Things) devices, etc., compared with batteries having non-flat discharge curves and high internal resistance, for example, alkaline batteries and other non-lithium batteries. Consequently, the latter types of batteries may have more limited utilization in electronic devices.

Often with battery powered devices, determining the internal resistance of a battery is useful for many reasons including for example to improve battery efficiency, safety, longevity, and optimal performance in various applications. It would be advantageous to have a mechanism that is capable of periodically determining the internal resistance of a battery that requires minimal to no extra hardware and compute requirements from the battery power supply circuit.

### SUMMARY OF THE INVENTION

A novel and useful apparatus and method of determining battery internal resistance for use in a battery power supply (BPS) circuit is described. The BPS circuit is operative to power an intermittently powered load and optimized to maximize battery capacity utilization and extend battery life, while offering low temperature performance. The BPS includes a voltage converter connected in series to a battery and generating a desired output voltage from the battery voltage, a current limiter connected in series to the voltage converter and configured to limit current from the battery when in a current limiting mode and provide a shunt in a noncurrent limiting mode, a capacitor tank connected in series to the current limiter for providing an output voltage to the load and first charged to a voltage up to either 95 or 100% (depending upon the operation of the BPS) of a desired output voltage while current limiting is on, and second charged to the desired output voltage when the current limiter is shunted.

An optional relaxation/stabilization period may then be applied before the load is enabled to maximize both battery capacity utilization and battery life. In addition, the BPS provides the ability to handle batteries with voltage greater or less than that of the output of a voltage converter by incorporating a buck-boost converter circuit. Further, the BPS provides a low power mode of operation while the load is disabled or in a sleep mode of operation.

The mechanism of the present invention is capable of periodically determining the internal resistance of a battery connected to the BPS circuit. It requires minimal to no extra hardware and compute requirements as it takes advantage of the components and controller that already make up the battery power supply circuit.

Several advantages of determining the internal resistance of a battery are described below. Determining the internal resistance of a battery is crucial for ensuring its efficiency, safety, longevity, and optimal performance in various applications.

It is well known that the internal resistance of a battery affects its overall performance. High internal resistance can cause significant voltage drops under load, reducing the efficiency and power output of the battery. By measuring internal resistance, the battery's ability to deliver power efficiently can be assessed.

The internal resistance of a battery typically increases with age and usage. Monitoring changes in internal resistance can provide insights into the health and remaining lifespan of the battery. This is particularly useful for maintenance and predicting when a battery might need to be replaced. Periods of high and low load internal resistance can be identified, and correlated with specific operations of the load, which could be optimized to reduce power consumption.

Batteries with high internal resistance can generate excessive heat during operation, which can lead to thermal runaway, leakage, or even explosions in extreme cases. Knowing the internal resistance helps in identifying potential safety risks.

High internal resistance leads to energy losses in the form of heat. By minimizing internal resistance, the energy efficiency of the battery system can be maximized, which is beneficial for applications where energy conservation is important.

The internal resistance affects the charging characteristics in the case of a rechargeable battery. Knowing the internal resistance helps in designing optimal charging algorithms that can reduce charging time while preventing damage to the battery.

Different applications require batteries with specific characteristics. By knowing the internal resistance, a circuit designer can select the appropriate battery type and design systems that match the battery's capabilities, ensuring reliable operation.

For complex battery systems, measuring internal resistance aid in diagnosing problems and identify faulty cells. This information is valuable for maintenance and ensuring the overall reliability of the battery system.

There is thus provided in accordance with the invention, a method of determining battery internal resistance for use in a power supply for providing battery based power to a load and that incorporates one or more current charging surges, comprising measuring a first battery voltage and a first capacitor tank voltage at a first sampling point before one of the current charging surges, calculating a first battery discharge current based on said first battery voltage and said first capacitor tank voltage, measuring a second battery voltage at a second sampling point after said current charging surge, calculating a second battery discharge current based on said first capacitor tank voltage, and estimating said battery internal resistance in accordance with said first battery voltage, said first battery discharge current, said second battery voltage, and said second battery discharge current.

There is also provided in accordance with the invention, a method of determining battery internal resistance for use in a power supply for providing battery based power to a load and that incorporates one or more current charging surges, comprising measuring a first battery voltage V_{BAT1} and a first capacitor tank voltage V_{CT1} at a first sampling point SP1 before a current charging surge, calculating a first battery discharge current I_{BAT1} in accordance with I_{BAT1}=I_{R}_{_{CL}}/ K where K is a conversion coefficient of a voltage converter and given by K=V_{BAT1}/V_{CT1} and I_{R}_{_{CL}} is the current through a current limiter coupled to the output of the voltage converter and given by I_{R}_{_{CL}}=V_{DC}−V_{CT1}/R_{CL} where V_{DC} is the output of the voltage converter and R_{CL} is the resistance of the current limiter, measuring a second battery voltage V_{BAT2} at second sampling point after said current charging surge, calculating a second capacitor discharge current I_{CT2} based on said first capacitor tank voltage V_{CT1} and V_{DC} in accordance with

$${I}_{CT 2} = C * \frac{{V}_{DC} - {V}_{CT 1}}{T}$$

where C is the capacitance of the capacitor tank, and T is a time interval, calculating a second battery discharge current I_{BAT2} in accordance with

$${I}_{BAT 2} = \frac{{I}_{CT 2}}{K} ,$$

and estimating said battery internal resistance R_{BAT} in accordance with

$${R}_{BAT} = \frac{{V}_{BAT 1} - {V}_{BAT 2}}{{I}_{BAT 2} - {I}_{BAT 1}} .$$

There is further provided in accordance with the invention, a battery power supply (BPS) circuit for providing power to a load, comprising a voltage converter connected to a battery and operative to generate a desired output voltage, a current limiter connected in series to said voltage converter and operative to limit the current output thereof, a capacitor tank electrically connected to said current limiter and to the load, a controller configured to estimate internal resistance of the battery by measuring a first battery voltage and a first capacitor tank voltage at a first sampling point before a current charging surge, calculating a first battery discharge current based on said first battery voltage and said first capacitor tank voltage, measuring a second battery voltage at a second sampling point after said current charging surge, calculating a second battery discharge current based on said first capacitor tank voltage, and estimating said battery internal resistance in accordance with said first battery voltage, said first battery discharge current, said second battery voltage, and said second battery discharge current.

There is also provided in accordance with the invention, a battery power supply (BPS) circuit for proving power to a load, comprising a voltage converter connected to a battery and operative to generate a desired output voltage, a current limiter connected in series to said voltage converter and operative to limit the current output thereof, a capacitor tank electrically connected to said current limiter and to the load, a controller configured to estimate internal resistance of the battery by measuring a first battery voltage V_{BAT1} and a first capacitor tank voltage V_{CT1} at a first sampling point SP1 before one of the current charging surges, calculating a first battery discharge current I_{BAT1} in accordance with

$${I}_{BAT 1} = \frac{{I}_{{R}_{CL}}}{K}$$

where K is a conversion coefficient of a voltage converter and given by

$$K = \frac{{V}_{BAT 1}}{{V}_{CT 1}} and {I}_{{R}_{CL}}$$

is the current through the current limiter and given by

$${I}_{{R}_{CL}} = \frac{{V}_{DC} - {V}_{CT 1}}{{R}_{CL}}$$

where V_{DC} is the output of the voltage converter, and R_{CL} is the resistance of the current limiter, measuring a second battery voltage V_{BAT2} at a second sampling point after said current charging surge, calculating a second capacitor discharge current I_{CT2} based on said first capacitor tank voltage V_{CT1} and V_{DC} in accordance with

$${I}_{CT 2} = C * \frac{{V}_{DC} - {V}_{CT 1}}{T}$$

where C is the capacitance of the capacitor tank, and T is a time interval, and calculating a second battery discharge current I_{BAT2} in accordance with

$${I}_{BAT 2} = \frac{{I}_{CT 2}}{K} ,$$

and estimating said battery internal resistance R_{BAT} in accordance with

$${R}_{BAT} = \frac{{V}_{BAT 1} - {V}_{BAT 2}}{{I}_{BAT 2} - {I}_{BAT 1}} .$$

There is further provided in accordance with the invention, an apparatus for determining battery internal resistance for use in a data logger, comprising a data logger including a plurality of sensors, each sensor generating sensor data, a log memory for storing sensor data generated by each sensor, a cellular modem for transmitting the sensor data to a cloud server, a battery power supply (BPS) circuit coupled to a battery, a first controller, said battery power supply circuit having one or more current charging surges and including a second controller operative to measure a first battery voltage and a first capacitor tank voltage at a first sampling point before one of the current charging surges, calculate a first battery discharge current based on said first battery voltage and said first capacitor tank voltage, measure a second battery voltage at a second sampling point after said current charging surge, calculate a second battery discharge current based on said first capacitor tank voltage, and estimate said battery internal resistance in accordance with said first battery voltage, said first battery discharge current, said second battery voltage, and said second battery discharge current.

There is also provided in accordance with the invention, an apparatus for determining battery internal resistance for use in a data logger, comprising a data logger including a plurality of sensors, each sensor generating sensor data, a log memory for storing sensor data generated by each sensor, a cellular modem for transmitting the sensor data to a cloud server, a battery power supply (BPS) circuit coupled to a battery, a first controller, said battery power supply circuit having one or more current charging surges and including a second controller operative to measure a first battery voltage V_{BAT1} and a first capacitor tank voltage V_{CT1} at a first sampling point SP1 before a current charging surge, calculate a first battery discharge current I_{BAT1} in accordance with

$${I}_{BAT 1} = \frac{{I}_{{R}_{CL}}}{K}$$

where K is a conversion coefficient of a voltage converter and given by

$$K = \frac{{V}_{BAT 1}}{{V}_{CT 1}}$$

and I_{R}_{_{CL}} is the current through a current limiter coupled to the output of the voltage converter and given by

$${I}_{{R}_{CL}} = \frac{{V}_{DC} - {V}_{CT 1}}{{R}_{CL}}$$

where V_{DC} is the output of the voltage converter and R_{CL} is the resistance of the current limiter, measure a second battery voltage V_{BAT2} at second sampling point after said current charging surge, calculate a second capacitor discharge current I_{CT2} based on said first capacitor tank voltage V_{CT1} and V_{DC} in accordance with

$${I}_{CT 2} = C * \frac{{V}_{D C} - {V}_{C T 1}}{T}$$

where C is the capacitance of the capacitor tank, and T is a time interval, calculate a second battery discharge current I_{BAT2} in accordance with

$${I}_{B A T 2} = \frac{{I}_{C T 2}}{K} ,$$

and estimate said battery internal resistance R_{BAT} in accordance with

$${R}_{B A T} = \frac{{V}_{B A T 1} - {V}_{B A T 2}}{{I}_{B A T 2} - {I}_{BAT 1}} .$$

### BRIEF DESCRIPTION OF THE DRAWINGS

The figures illustrate generally, by way of example, but not by way of limitation, various embodiments discussed in the present document. For simplicity and clarity of illustration, elements shown in the figures have not necessarily been drawn to scale. For example, the dimensions of some of the elements may be exaggerated relative to other elements for clarity of presentation. Furthermore, reference numerals may be repeated among the figures to indicate corresponding or analogous elements. References to previously presented elements are implied without necessarily further citing the drawing or description in which they appear. The number of elements shown in the figures should by no means be construed as limiting and is for illustrative purposes only.

FIG. 1 is a block diagram illustrating an example battery power supply (BPS) with a voltage converter for use with intermittently operating devices constructed in accordance with an embodiment of the present invention;

FIG. 2 is a schematic diagram illustrating an example BPS, optionally an IoT system or other type of high power consumption, intermittently operating system, including a BPS, constructed in accordance with the present invention;

FIG. 3 is a flow diagram illustrating an example method of operation of the BPS of FIG. 1 when powering an intermittently operating (i.e. switching) device, optionally when switching the load between an unpowered state, and a powered state, in accordance with an embodiment of the present invention;

FIG. 4 is a graph illustrating exemplary charging curve of the capacitor tank voltage in the BPS of FIG. 1 for a full off-on-off cycle, optionally when operating per the method shown in the flow chart of FIG. 3, according to an embodiment of the present invention;

FIG. 5 is a graph illustrating battery current I_{BAT} versus time for a full off-on-off cycle of the BPS;

FIG. 6 is a graph illustrating battery voltage over time for an example 1.5V battery cell;

FIG. 7 is a graph illustrating battery current, battery voltage, and capacitor tank voltage over time;

FIG. 8 is a flow diagram illustrating an example method for determining battery internal resistance;

FIG. 9 is a graph illustrating battery internal resistance overtime for an example alkaline battery; and

FIG. 10 is a block diagram illustrating an example application of the BPS circuit in a data logger device.

### DETAILED DESCRIPTION

### Battery Power Supply Circuit

Applicants have realized that use of lithium and lithium-ion batteries in IoT devices and other relatively high power consumption devices, may include a number of drawbacks as these types of batteries are hazardous, restricted in transportation and usage, and expensive. Consequently, applicants have realized that there is a need for an apparatus and for methods to power a wide class of IoT devices and other relatively high power consumption devices without degrading their critical operational characteristics, and which employ batteries such as alkaline batteries and other batteries which have widespread availability and are devoid of the disadvantages of lithium-chemistry batteries. Such an apparatus, or “battery power supply” as referred to hereinafter, in some embodiments, may be suitable for use with any type of “periodic switching” or “on and off” device or any device with different load current profiles in different states. Examples of such devices may include cellular 2G/3G/4G/5G modems, RF transceivers, and sensors, among others.

An aspect of the present invention relates to a battery power supply (BPS) including electronic circuitry configured to be connected to one or more batteries (hereinafter “battery”) possessing non-flat discharge curves and high internal resistance, optionally non-linear, and to replicate the output characteristics of a power source possessing a battery with a flat discharge curve and low internal resistance (e.g., lithium batteries, lithium-ion batteries, nickel-metal hydride (NiMH) batteries, or batteries with flat discharge curves or low internal resistance). The electronic circuitry may include analog components, digital components, and control logic configured to adjust the operating parameters of the BPS to maintain its stability over a wide temperature range, optionally when connected to intermittently operating loads. The electronic circuitry may include a voltage converter, pre-charging circuitry including a current limiter, storage capacitors having large-value capacitance and low output impedance, a voltage regulator, and a control unit (i.e. controller) to control the electronic circuitry thereby providing current to the intermittently operating load. Optionally, the battery and/or the load may be included in the BPS circuit. Optionally, the load may include an intermittently operating IoT device and other relatively high power switching loads. For example, an intermittently operating load may include a capacitor.

Embodiments pertain to a battery based power supply (BPS) circuit to power an intermittently operated load, optimized for battery capacity utilization and extended battery life, while also offering low temperature performance. The power supply includes one or more batteries, a voltage converter configured to be serially connected to a battery and to output a desired voltage V_{DC} from a battery voltage V_{BAT}, a current limiter serially connected to the voltage converter and configured to limit outrush current from the battery while in a current limiting mode and to substantially provide a short circuit in a non-current limiting mode, a capacitor tank serially connected to the current limiter for providing an output voltage V_{OUT} to the load, and configured to be charged to a threshold voltage V_{TH} up to 95% of the desired V_{OUT} while the current limiter is switched to the current limiting mode, and is configured to be charged to close to V_{OUT} while the current limiter is switched to the non-current limiting mode, a control unit which measures voltages, controls the operation of the voltage converter and current limiter, activates the load, and calculates the battery internal resistance.

In some examples, the period of time of charging to the threshold voltage V_{TH} automatically compensates for variations in temperature and other variations in the device. This and the other features of the BPS of the present invention aid in enabling the device to operate in low temperatures.

The features of the present invention includes partial use of the current limiter, use of intermittent current draw from battery, relaxation of the battery prior to activation of the load, and the optional relaxation period between uses of the battery serve to extend battery life. Note that the term desired output voltage V_{OUT} is intended to mean the voltage output of the BPS (i.e. across the capacitor tank) that is supplied to the load device while the load is enabled and performing its function. It represents the voltage naturally present on the capacitor with the voltage converter enabled, no current limiting (i.e. shunt applied), and at steady state before the load is enabled. It other words, it is the voltage that is desired to be presented to the load before the load is enabled. It is acknowledged that V_{OUT} has several non-final values as the capacitor tank is charged during one or more current charge surge profile stages.

In alternative embodiments, the threshold voltage is not limited to 95% or less than the desired value of the output voltage but rather is less than the output of the voltage converter (i.e. less than 100% of the desired output voltage). Several applications of this alternative voltage threshold feature are described further infra.

In alternative embodiments, the relaxation period may or may not be included. Several applications that incorporate the relaxation period as well as several applications that exclude the relaxation period are described further infra.

In some embodiments, the electronic circuitry may include three states of operation. A first state where the load may be in unpowered mode (which may also be referred to hereinafter as “disabled”, “disabled state”, “disabled mode”, “powered off”, “off state”, “off mode”, “unpowered mode” or “unpowered state”), a second state where the load is in a relatively high-power consumption mode (which may also be referred to hereinafter as “powered mode”, “powered state”, “powered on”, “woken state”, “woken mode”, “on state”, “on mode”, “enabled state” or “enabled mode”), and a third state where the load is in a low power or sleep state (which may also be referred to hereinafter as “low power mode”, “low power state”, “sleep state” or “sleep mode”). In the first and third state, initially, the voltage converter may be set to an off mode associated with a disabled state of the converter, and the current limiter may be set to a current limiting state by the controller. In this first state, the storage capacitor (i.e. the capacitor tank) may be essentially disconnected from the battery. When the load is to be switched into the powered mode or woken up from sleep mode, the controller may first set the voltage converter to an on mode associated with an enabled state in the converter to apply an initial voltage through the current limiter on the storage capacitor to increase its charge. The controller, upon sensing the voltage on the storage capacitor and allowing for a first charging period, may disconnect the current limiter (i.e. causing a short circuit or shunting the circuit with a resistance that is less than the resistance of the circuit) to further increase the voltage on the storage capacitor and initiate a second charging period. The second charging period may be followed by an optional period of relaxation/stabilization. Following the aforementioned optional period of relaxation/stabilization, the controller may then place the load in the powered mode to draw high power current from the charged storage capacitor.

In some embodiments, the electronic circuitry may provide for protection of the battery against large current impulses and large inrush currents, and from battery drain by eliminating parasitic self-discharge currents of the storage capacitors while the load is turned off. The electronic circuitry may provide a first current surge to charge the storage capacitor(s) (i.e. capacitor tank) to a certain voltage in the process of turning on the load, followed by a gradual decrease in current when the capacitor tank is first charged. The electronic circuitry may then provide a second short current surge to the capacitor tank to bring the output voltage to the desired output voltage when current limiting is disconnected, optionally followed by a relatively long stabilization (i.e. relaxation) period (tens or hundreds of milliseconds) with a stable small (optionally milliamps range) discharge current, and then the full current when the load is powered on.

It may be appreciated that there are several advantageous features to the BPS of the present invention, in addition to serving to provide power to devices typically using batteries with flat discharge curves and a low internal resistance. The specific discharge profile formed by the first regulated surge to a first value with decreasing current, followed by a second short surge to a second value, followed by a subsequent low discharge current during stabilization, is well suited to the specific internal ion activity that is the basis of alkaline (and other) battery chemistries.

Consider an example application of the battery power supply circuit to lithium thionyl chloride (Li—SOCl2) primary cell batteries will now be described. In these batteries, electrolyte based on sulfonated thionyl chloride serves as the positive electrode. During use of these batteries, sulfation of the electrodes occurs which sharply reduces the battery's ability to deliver current. In other words, sulfation greatly increases the internal resistance of the battery. Sulfation is a time dependent, repeatable process. A sulfation layer is formed when the load is removed from the battery or subjected to a very low load current for 12 hours. To restore the battery's ability to deliver high current, this sulfation layer must be removed by applying a short, high current pulse. The second current surge of the present invention provides such a current pulse. The control unit or a microcontroller is operative to periodically apply short pulses of sulfation-breaking current to the battery. Using such a technique, the battery is desulphated automatically before the load is turned on for each power cycle of the load.

Furthermore, the BPS circuit has a fundamental feature of self-adaptation to environmental conditions, for example, to temperature variations, as well as self-adaptation to variations in component tolerances. It is noted that aluminum electrolytic capacitors with a low temperature rating of −55° C. generally exhibit a capacitance loss of between 10 and 20% when operating at −40° C. At the same time, any chemical battery exhibits a significant increase in internal resistance when operating at low temperatures. Thus, as the temperature decreases, the pre-charge current spike amplitude decreases, and consequently, the battery having increased internal resistance is less stressed.

In some embodiments, time-series data from periodical voltage measurements of the storage capacitors by the controller may be stored (e.g., in the controller) for use in a production testing stage to estimate the real capacity of the storage capacitors which may serve as an indication of the quality of the assembly, or in runtime to check its real state which may be useful and important for devices with an operational life possibly reaching or exceeding that of the electrolytic capacitors. This time-series data may be used locally by the device, or may be transmitted over communication channels from the device for use by remote services or applications. It is noted that, if the capacitance may be varied, the data may serve to adjust the capacitance accordingly.

In some embodiments, the BPS of the present invention may be integral to the device, with the battery built-in in the BPS or, alternatively, the battery may be separately replaceable. Optionally, the BPS may be a kit which may be adapted to existing devices, for example, through retrofit. It is noted that, although the BPS of the present invention is described herein as being operational with batteries possessing non-flat discharge curves and high internal resistance, optionally non-linear, the skilled person may readily appreciate that the BPS may also be used with batteries which have flat discharge curves, for example, lithium, lithium-ion batteries, and nickel-metal hydride batteries, and therefore its application is not limited to non-flat discharge curve batteries.

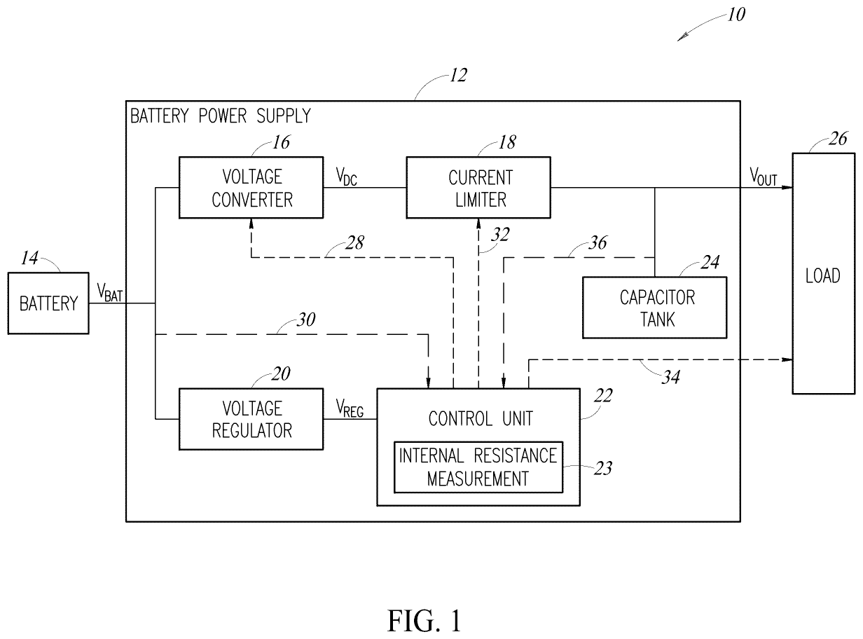

A block diagram illustrating an example battery power supply (BPS) with a voltage converter for use with intermittently operating devices constructed in accordance with an embodiment of the present is shown in FIG. 1. The BPS, generally referenced 10, includes a voltage converter 16, current limiter 18, capacitor tank 24, voltage regulator 20, control unit 22, battery 14, and load 26. The BPS is operative to supply DC power from the battery to the load. The battery has a non-flat discharge curve and a high internal resistance, generally associated with alkaline batteries and other types of non-lithium-chemistry batteries, or may have other discharge characteristics and/or other internal resistance characteristics, such as lithium or lithium-ion batteries and other types of batteries. Optionally, the load comprise an IoT device or other relatively high power consuming device generally powered by a lithium battery. Operational modes of the load may include periodic switching, optionally ON/OFF states, and/or different load current profiles in different states. Optionally, the battery and/or the load may be integrated within the BPS and the control unit may be external to the BPS.

The battery may include one or more batteries connected in series so that an output voltage V_{BAT} of the battery pack can be greater than, equal to, or less than the output voltage V_{OUT} required by the load, and will dictate the type of voltage converter, e.g., buck, boost, buck-boost, upconverter, downcoverter, etc. As previously mentioned, the battery may include batteries with a non-flat discharge curve and with a relatively high internal resistance, for example, alkaline batteries, and also batteries with other discharge curve and/or other internal resistance, such as, for example, lithium metal, lithium-ion, or nickel-metal hydride (NiMH) batteries, among others. Alternatively, the battery may comprise a single battery.

The voltage converter may include a DC/DC converter (e.g., buck converter) which downconverts voltage V_{BAT} to V_{DC} and is configured to be turned on (i.e. enabled) and off (i.e. disabled) by the control unit, described in more detail supra. Note that V_{DC} may be of a lesser voltage than V_{BAT} and greater than or equal to V_{OUT}.

The voltage regulator 20 may include a low current voltage regulator which may output a constant voltage VREG as the power source for the control unit, with V_{REG} optionally being less than, greater than or equal to V_{DC}. During “sleep” periods of the control unit, the voltage regulator output current, as an example, may be equal to or less than 10 μA. The voltage regulator may comprise a low voltage drop linear regulator with a wide input voltage range and low ground current which may be linearly dependent on the load current, optionally in the microcurrent region.

The current limiter may comprise any suitable type of current limiting circuit which can be controlled by the control unit to optionally either enable current limiting to a predetermined level or to disable current limiting essentially short circuiting the current limiter. The current limiter may support two or more current limiting levels. Note also that each current limiting level may exhibit either a fixed or continuously variable current limiting capability, with one of the levels optionally presenting essentially a short circuit. The current limiting predetermined level may be optionally determined by the size of the capacitor tank, the specific chemistry of the batteries used, and/or according to the implementation, and may be in the range of tens or hundreds of milliamps to several amps. The capacitor tank may comprise any type of capacitor, optionally a plurality of parallel connected capacitors, with low equivalent series resistance (ESR) and rated for voltages greater than or equal to V_{OUT}, and with a capacitance large enough for feeding relatively large, short current consumption surges demanded by the load. The load, as described infra, may comprise an IoT device or other relatively high power consuming device generally powered by, but not limited to, a lithium battery, for example, any cellular 2G/3G/4G/5G or other modem, an RF transceiver, a sensor, among others.

It is noted that the selection of the capacitor tank may be determined by the specific consumption profile of the load, and the capacity of the capacitor tank may be based on the characteristics of the battery. Protection of the battery from inrush current may be provided by the current limiter when the voltage converter is turned on and the capacitor tank is completely discharged. Furthermore, battery protection may be provided from the capacitor tank self-discharge current by the voltage converter being turned off. Therefore, use of a capacitor tank with a capacity of thousands of microfarads to farads, and self-discharge current at levels of milliamps or more, may be possible.

The control unit may be part of a device that incorporates the BPS power system or may be an integral part of the BPS. The control unit may comprise any processor based device, and may include any combination of hardware, software, and firmware. The control unit may be configured to measure V_{BAT} through monitoring signal 30, and voltage V_{OUT} across the capacitor tank through monitoring signal 36. The control unit can be configured to control operation, including enabling of voltage converter through control signal 28, and may additionally control operation of the current limiter through control signal 32 in order to set the current limiter to the predetermined current limiting level or to disable it. Additionally, the control unit may control operation of the load through control signal 34 in order to power the load on and off. It is noted that the monitoring signals 30 and 36, and the control signals 28, 32, and 34, may be implemented using any one, or combination of, analog and digital signals, including appropriate circuitry, including transmission buses as required.

The control unit may implement the required feedback to maintain BPS operation despite temperature variations and component tolerance variations. The control unit may also adjust operating parameters based on the type and requirements of the load, and/or battery charge level. The control unit may use monitoring signal 36 to measure V_{OUT}, and, responsively, may control the operation of the voltage converter and the current limiter by means of control signals 28 and 32, respectively. The control unit may use monitoring signal 30 to measure V_{BAT} and monitoring signal 36 to measure V_{OUT}, and by controlling the operation of the current limiter with control signal 32, may determine the battery charge level by indirectly measuring the internal resistance of the battery.

In addition, the control unit comprises a battery internal resistance measurement block 23 operative to calculate the internal resistance of the battery 14 on a periodic basis.

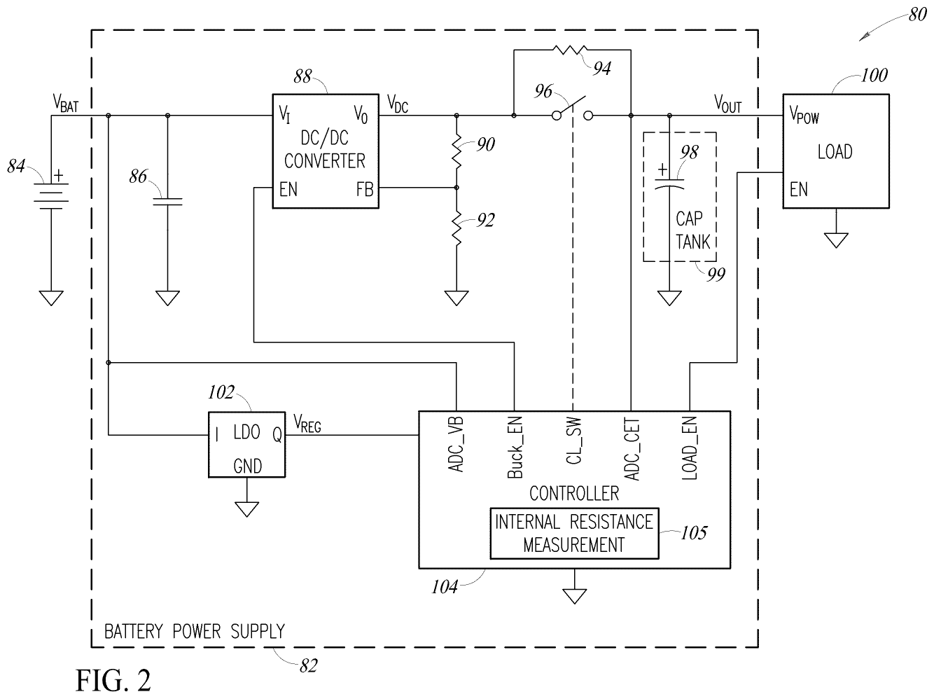

A schematic diagram of an example BPS, optionally an IoT system or other type of relatively high power consumption, intermittently operating system is shown in FIG. 2. The system, generally referenced 80, may additionally include a non-flat discharge, high internal resistance multicell battery 84 and a connected load 100. Alternatively, the battery may include one or more batteries with flat discharge curve characteristics, for example, but not limited to lithium batteries or lithium ion batteries. Optionally, the BPS 80, battery 84, low drop out voltage regulator 102, and load 100 may be functionally similar to the BPS 10, battery 14, voltage regulator 20, and load 26 of FIG. 1, respectively.

The DC/DC converter 88 with feedback resistors R1 90 and R2 92 may comprise any well-known high speed DC/DC converter to implement the voltage converter (nonessential implementation details are omitted). R1 90 and R2 92 form an analog feedback circuit used to assess the performance of the DC/DC converter by periodic or real time (based on comparators) measurement of the feedback (FB) voltage thereof by the converter 88. During normal operation of the converter 88, the feedback voltage may be equal to the voltage of the internal reference voltage source of the converter known from the manufacturer's data sheets, which may be used to check the operability of the converter 88. Note that the converter may not only serve as a voltage converter, but also as a controlled switch with enable/disable states controlled by the Buck_EN signal of the controller (control signal 28 in FIG. 1).

The regulator 102 may implement the voltage regulator 20 (FIG. 1) and may comprise a low dropout (LDO) regulator. Switch 96 and R_{CL} 94 together may implement the current limiter in FIG. 1. The switch may comprise any electronically controlled switch, for example, a p-type MOSFET, with a low resistance in the closed state. The switch may be controlled by signal CL_SW (control signal 32 in FIG. 1). R_{CL} 94 may comprise a current limiting resistor. In combination with the DC/DC converter and the capacitor tank 99, the current limiter circuit may form a capacitor precharge system where the converter 88 and switch 96 may form a two switch series combination. It is noted that R_{CL} 94 together with feedback resistors R1 90 and R2 92 may serve as a “bleeder” circuit for the capacitor tank 99 when the converter 88 is disabled.

The load 100 may comprise any intermittently activated load having an enable (EN) control input which turns the load on and off (load 26 in FIG. 1). The controller 104 may comprise any suitable controller to control the operation of the BPS as described supra and with reference to the operation of BPS 10 and control unit 22 in FIG. 1. In addition, the controller comprises a battery internal resistance measurement block 105 operative to calculate the internal resistance of the battery 84 on a periodic basis.

Note that Vᵢ and Vₒ of the DC/DC converter correspond to V_{BAT} and V_{DC} in FIG. 1, respectively. Additionally, I and Q in the LDO regulator 102 correspond with V_{BAT} and V_{REG} in FIG. 1, respectively. Furthermore, the ADC_CET signal corresponds to V_{OUT} in FIG. 1 and V_{POW} with V_{OUT} in FIG. 1.

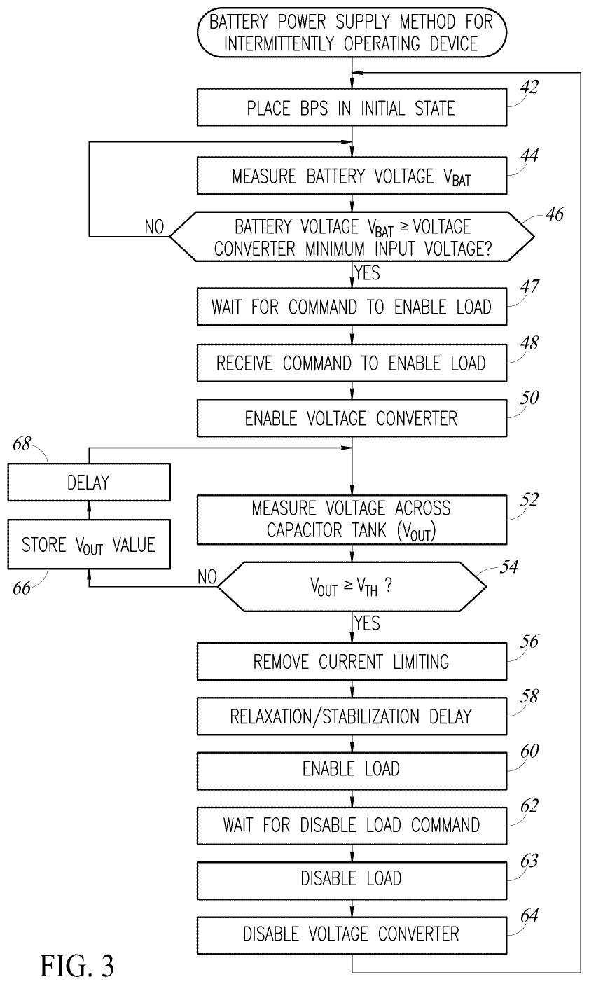

A flow diagram illustrating an example method of operation of the BPS of FIG. 1 when powering an intermittently operating (i.e. switching) device, optionally when switching the load between an unpowered state, optionally low powered, and a powered state is shown in FIG. 3. In one embodiment, the method is implemented by the control unit. With reference also to FIG. 1, the BPS is first placed in an initial state (step 42). The voltage converter is turned off (i.e. disabled), the current limiter is enabled and in current limiting mode at a predetermined current limiting level, the capacitor tank is discharged or in an unknown state, the voltage regulator is in an always ON state so that it is continuously operational and supplies power to the control unit, and the load is powered off.

The battery voltage V_{BAT} is measured through monitoring signal 30 (step 44) at predetermined intervals of time or continuously. It is then checked whether V_{BAT} is greater than or equal to the minimum input voltage of the voltage converter (i.e. if the battery voltage under light load is sufficient to start the voltage converter) (step 46). If it is not, the method returns to step 44. Note that troubleshooting efforts may be made to determine whether the battery is faulty or drained. If V_{BAT} is sufficiently high (step 46), the system waits for a command to enable the load (step 47). Once the command is received, the load is enabled (step 48). Note that the command may be internal or external to the BPS.

The voltage converter is then enabled and turned on (step 50) via control signal 28 which functions as an enable signal. Note that the voltage converter is enabled sufficiently in advance of the expected operation of the load, so that the capacitor tank can be sufficiently charged to power the load. On the other hand, it is not desirable to charge the capacitor tank too early where it sits idle at full charge for an excessive amount of time since during idle time, the battery is drained unnecessarily due to leakage current across the capacitor tank. The voltage converter functions to generate V_{DC} which is input to the current limiter. Note that the current limiter is in current limiting mode, and together with the capacity of the capacitor tank, dictates the time (i.e. delay) required to charge the capacitor tank to a threshold voltage V_{TH}. Note further that V_{TH} is a voltage up to 95% of a desired V_{OUT}. Alternatively, V_{TH} is a voltage less than 100% of a desired V_{OUT} depending on whether a relaxation time period is incorporated.

It is noted that the term threshold voltage V_{T}H is used repeatedly in descriptions of the operation of several BPS embodiments. The value of the threshold voltage in each case is not necessarily the same and can vary from one embodiment or example to another. In each case, however, the term represents the voltage at which a current surge ends, and in some cases where an additional current surge begins.

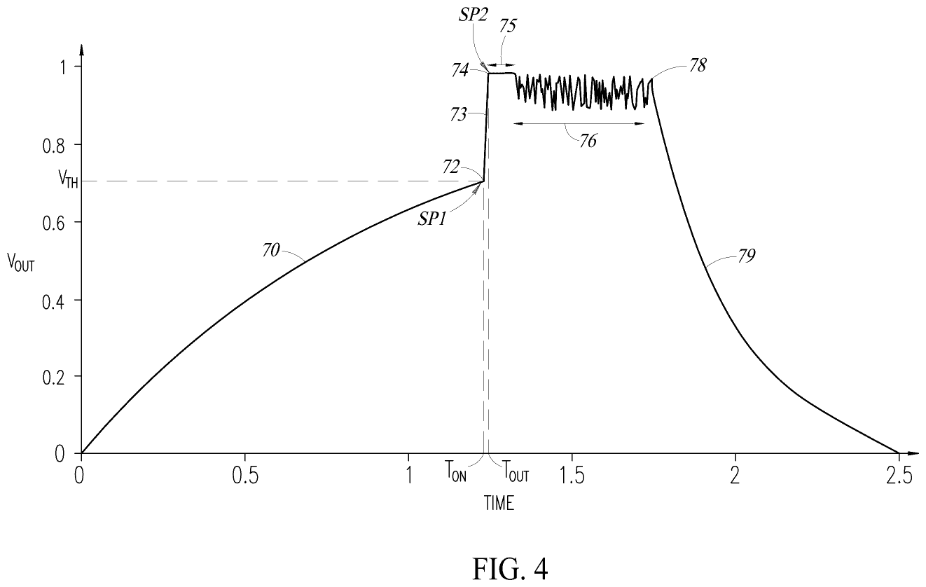

A graph illustrating exemplary charging curve of the capacitor tank voltage in the BPS of FIG. 1 for a full off-on-off cycle, optionally when operating per the method shown in the flow chart of FIG. 3 is shown in FIG. 4. It is appreciated that the following voltage relationship may be present in the BPS: V_{BAT}>=V_{DC}>=V_{TH}.

Initially, the voltage converter is disabled and turned off. At time zero, it is turned on and the capacitor tank begins charging with a corresponding first spike in current. The charging curve 70 represents normal exponential voltage rise while charging through the enabled current limiter. The control unit continuously or periodically measures V_{OUT} via monitoring signal 36 (step 52).

Each measurement of V_{OUT} is compared to V_{TH} (step 54) which is the expected threshold voltage value to be attained while the current limiter is enabled. V_{T}H is a value up to 95% of the desired V_{OUT}. If V_{OUT}<V_{TH} the value of V_{OUT} is optionally stored for later use in a production testing stage (step 66). A delay is then introduced (step 68) which is less than that introduced by the RC combination of the current limiting resistor and capacitor tank. The amount of the delay can be determined based on the RC time constant of the combination of the current limiter and the capacitor tank, along with an allowable error in detecting voltage equality across the capacitor tank and V_{TH}. For example, considering an error of 0.1V in performing the comparison, and based on the given RC time constant, it is known that the minimum time to charge the capacitor tank by 0.1V is Tₘᵢₙ. Therefore, the time delay can be set to Tₘᵢₙ.

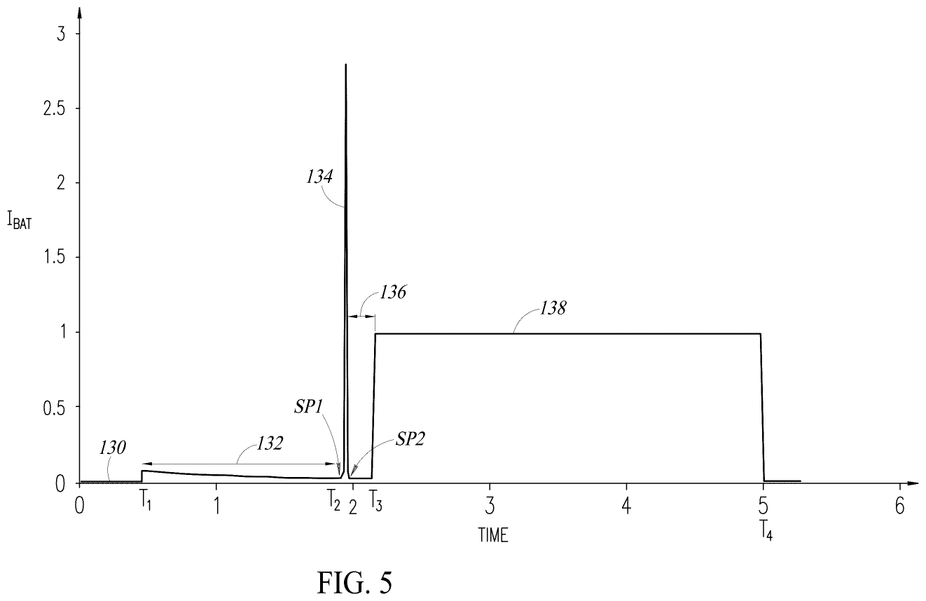

When V_{OUT}≥V_{TH} (step 54), the current limiter is removed and replaced with a short circuit (step 56). At this point (72 in FIG. 4), the specified threshold voltage relative to the output of the voltage converter has been reached and the shunt switch closes 96 (FIG. 5). At this point, the capacitor tank continues to charge towards the desired V_{OUT}. The voltage across the capacitor tank jumps almost instantaneously with a corresponding second spike in current (73 in FIG. 4). Note that V_{OUT} increases and approximates the desired V_{OUT} (74 in FIG. 4) which is the output of the voltage converter V_{DC}. It technically does not reach this voltage due to a small finite resistance remaining in any possible implementation of the current limiter despite the theoretical short circuit. Note also that it may not be necessary for capacitor tank to be fully charged at this point, and that the additional charging may be provided by the short circuit in the current limiter created by the shunt.

Following the jump in V_{OUT} after removing current limiting, a time delay is optionally introduced (75 in FIG. 4) to allow for the relaxation/stabilization of both the capacitor tank charge and the ions within the battery. In one embodiment, the value of the relaxation/stabilization delay may be tens or hundreds of milliseconds and may be optimized based on the chemistry of the particular batteries to be used in the implementation of the BPS.

Following the optional relaxation/stabilization delay, the load is turned on (i.e. enabled, powered on) (step 60). The load begins drawing current required for its operation from the charged capacitor tank and the output of the voltage converter (76 in FIG. 4). The load remains in the enabled state until the control unit receives a disable load command (step 62). When received, the control unit disables the load via control line 34 (78 in FIG. 4) (step 63) and turns the voltage converter off (step 64). Note that the control unit optionally waits for and receives an external command to disable the load. While the load is operating, it receives power from the capacitor tank. The control unit maintains the states of the control outputs while waiting for the command to deactivate the load. The method then returns to step 42 whereby the BPS is placed in the initial state again to complete the cycle.

When the capacitor tank is disconnected from the battery by disabling the voltage converter, it begins discharging with a relatively low discharge current (79 in FIG. 4) via a path to ground.

Note that the method of FIG. 3 may be repeated for each cycle of operation of the load from an off (unpowered) state or sleep (low power) state to an on (powered) state and back again to off. It is also noted that one skilled in the art may practice the teachings of the method described by the method of FIG. 3 using more or less steps, and/or a different sequence of steps.

Note further that during the operation of the BPS, the battery may experience a number of variable conditions. Initially, when the capacitor tank begins to charge, the battery may first see a relatively sharp surge of current, the amplitude of which may be determined by the value of the resistance in the current limiter, the real capacitance of the capacitor tank, the remaining charge in the capacitor tank (if the capacitors are not fully discharged), and the ratio of V_{BAT} to V_{DC}. The battery may experience a strong discharge current that decreases over the charging cycle with the current limiter in the current limiting mode. When the current limiter is shorted the battery may experience a second sharp surge of current. Following this second surge, the optional battery stabilization (i.e. relaxation) period is initiated. During this period, the battery discharge current may be low yet may be greater than at initialization (step 42) as it may be equal to a sum of the control unit operating current, the parasitic current drawn by the load in an off state, the self-discharge current of the capacitor tank, the current drawn by the voltage regulator in the on state, and the current drawn by the voltage converter.

In some embodiments, the BPS turns off the load by transferring control to a subroutine executable by the control unit. The control unit may power off the load and then disable the voltage converter in sequence without delay or with the necessary delay if the load requires it. Note that this applies regardless of the type of converter, i.e. converter, buck-boost converter, etc., or whether or not the load is sleep capable. As a result, the capacitor tank may be disconnected from the battery and its leakage current does not discharge the battery.

The following is a description of an exemplary operation of system 80, in accordance with an example embodiment of the present invention. The description may reflect some or all of the steps shown in the flow diagram of FIG. 3. Note that initially the DC/DC regulator is in the disabled state, switch 96 is open (i.e. R_{CL} 94 provides current limiting), and the LDO regulator 102 is continuously enabled.

To turn the load on, the controller 104 first enables the DC/DC converter. Signal ADC_CET provides periodic measurements (i.e. sampling) of V_{OUT} on the capacitor tank 99 to the controller. Since the switch is in the open state, the capacitor tank is charged through R_{CL} 94. When V_{OUT} reaches a predetermined threshold V_{T}H, the controller closes the switch via the CL_SW signal thereby short circuiting R_{CL} and causing V_{OUT} to increase to its desired value. After the optional relaxation/stabilization delay (which may be optional depending on the implementation), the controller activates LOAD_EN to enable the load.

The graph of FIG. 4 illustrates charging the capacitor tank, optionally when operating per the method of FIG. 3. The normalized voltage across the capacitor tank V_{OUT} is shown versus normalized time. The charging curve rises exponentially from V_{OUT}=0 at T=0 (70 FIG. 4) where the voltage converter is turned on. V_{OUT} rises to a threshold voltage V_{TH} at T=Tₒₙ, the time constant dictated by the resistance of the current limiter and the capacitance of the capacitor tank. At Tₒₙ, due to the removal of the current limiting resistor, V_{OUT} increases to approximately the desired V_{OUT} at time T=Tout with V_{OUT}=desired V_{OUT} at T=Tₒᵤₜ.

Note that in general, if a BPS embodiment includes a relaxation period, then the threshold voltage is less than 100% of the desired output voltage. If the BPS embodiment does not include a relaxation period, than the threshold voltage is up to 95% of the desired output voltage. This applies regardless of the type of converter, i.e. converter, buck-boost converter, etc., or whether the load is sleep capable or not.

### Determining Battery Internal Resistance

Internal resistance (IR) in a battery is the opposition to current flow within it. This internal resistance consists of two main components: (1) electronic resistance and (2) ionic resistance. The combination of these two components is known as the total effective resistance.

Electronic resistance includes the resistivity of materials such as the metal covers and internal components, as well as the quality of the contacts between these materials. The impact of this part of the total effective resistance is immediate, observable within the first few milliseconds after the battery is subjected to a load.

Ionic resistance refers to the opposition to current flow within the battery due to electrochemical factors like electrolyte conductivity, ion mobility, and electrode surface area. These polarization effects occur more gradually than electronic resistance, typically beginning a few milliseconds or more after the battery is placed under load.

The impact of electronic and ionic resistance can be observed using a dual current surge test. The test includes placing a battery on a low background drain allowing it to first stabilize and then pulsing it with a heavier load for a short duration, e.g., 100 milliseconds. Using the well-known Ohms law, the total effective resistance can be calculated by dividing the change in voltage by the change in current.

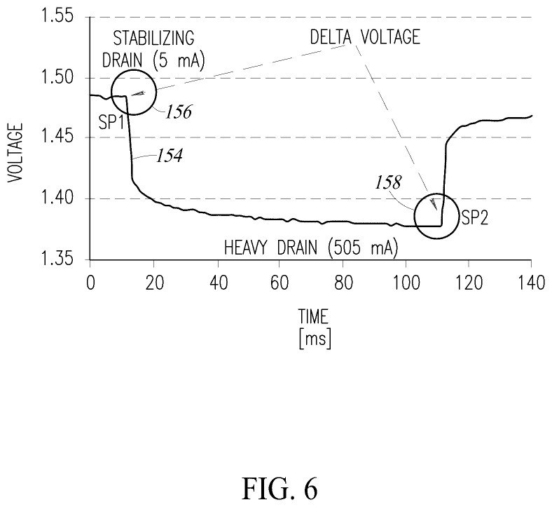

Consider a graph 154 illustrating battery voltage over time for an example battery as shown in FIG. 6. In this example, if a 5 mA stabilization load is used in combination with a 505 mA current surge, the change in current is 500 mA. If the voltage changes from 1.485 (detail circle 156) to 1.378 (detail circle 158), the delta voltage would be 0.107 Volts, thus yielding a total effective resistance of 0.107 Volts/500 mA or 0.214 Ohms.

It is noted that the voltage drop of a battery under load is a function of its total effective resistance and current drain rate. An estimate of initial voltage drop under load can be calculated by multiplying the total effective resistance by the current drain placed on the battery.

Thus, internal resistance can be calculated based on the voltage drop of the battery under a known load. It is appreciated that calculation results are affected by technique, settings and environmental conditions.

The dual surge technique of determining internal resistance of a battery can be applied to the battery power supply circuit described supra in connection with FIGS. 1 through 5. Note that most of the current spikes in the BPS circuit are determined by the capacitor and voltage converter while the voltage converter is within its operational range. The conversion coefficient K (calculation of which is defined infra) being battery voltage dependent, impacts the amplitudes of the current spike.

Measurements of both battery voltage and capacitor voltage are taken before the load is enabled. These measurements are not fundamentally necessary for the operation of the BPS circuit. If the internal resistance of the battery is to be estimated, however, they are necessary to be performed.

Note that the BPS circuit does not provide any direct method of converting current to voltage other than a current limiting resistor or a known current limiting level. In one embodiment, the BPS circuit is not adapted to measure current but rather only voltage. Therefore, it is appreciated that mechanism of the present invention does not measure the converted by any kind of transducer voltages to estimate currents what is necessary to estimate internal resistance of the battery.

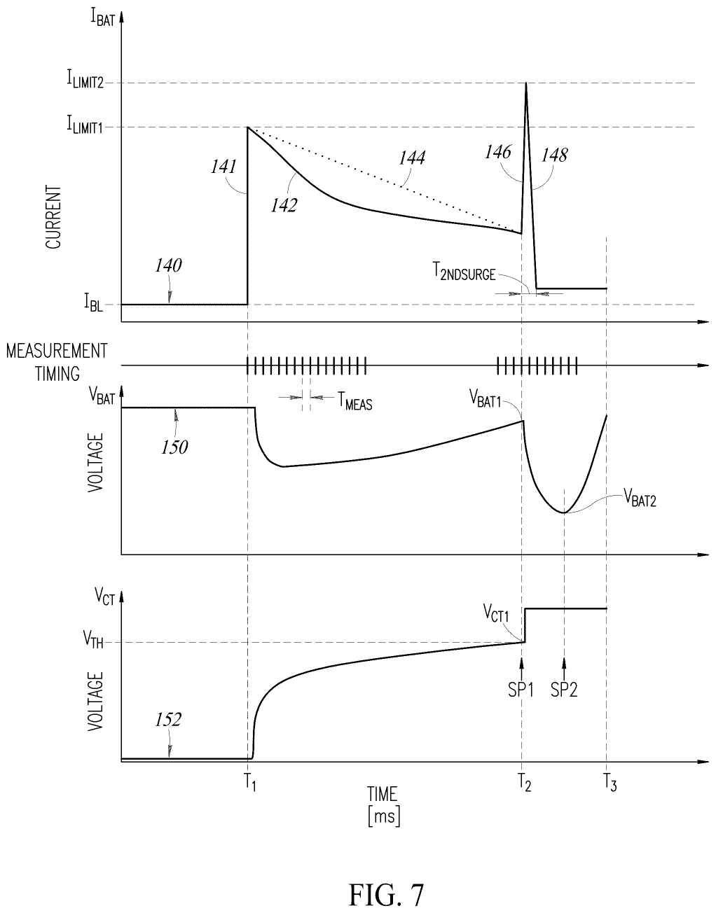

Three different profiles of the BPS circuit are shown in FIG. 7. The three profiles illustrate battery current I_{BAT} (trace 140), battery voltage V_{BAT} (trace 150), and capacitor tank voltage VCT (trace 152) over the same timeline. In addition, the timing of voltage measurements are shown and indicated as MEAS and arranged along the same timeline, the time between measurements (i.e. period of sampling) is TMEAS.

With reference also to FIGS. 2 and 3, at time T<T₁ the BPS is in a baseline state 140 (typically sub milliamp) (i.e. disabled or in sleep mode) with the load in either the off or sleep state where I_{BAT} is substantially equal to zero other than minimal current I_{BL} required to power the voltage regulator and the control unit. The capacitor tank 99 is in the discharged state and V_{OUT} is zero.

At time T₁, the voltage converter 88 is enabled and inrush current flows to the capacitor tank via current limiting resister R_{CL} 94, shown by an almost instantaneous rise 141 in I_{BAT} to the predetermined value I_{LIMIT1}. The current surge at 141 corresponds to the first surge of the dual surge test. Note that the sample point (SP1) occurs later in time. Battery current I_{BAT} then decreases exponentially 142 (or linearly 144 or by any physically implementable curve) in accordance with the increase in V_{OUT} across the capacitor tank until it reaches a threshold voltage V_{TH} up to 95% of the desired V_{OUT} at time T=T₂. Note that the battery discharge current at time T₂ is determined by the initial charge of the capacitor tank, its capacitance and voltage V_{TH}.

Use of the term ‘predetermined’ is intended to refer to values that are predetermined (such as threshold voltage) but may also refer to values that are dynamic. Applications of the mechanism of the present invention may incorporate one or more dynamically set values.

At the first sampling point (SP1) of the dual surge test, which corresponds to time T₂, the capacitor voltage V_{CT} becomes equal or greater than the threshold voltage V_{T}H. Both the capacitor voltage V_{CT1} and the battery voltage V_{BAT1} are measured. This is the point just as the end of the first surge, and just before the start of the second current surge (as indicated by V_{BAT1} measured at sampling point SP1 in FIG. 7). Note that it is exactly at this moment in time that the capacitor tank is still connected to the output of the DC/DC converter through the current limiting resistor R_{CL} since the closing of the shunt switch requires a finite additional amount of time. Thus, at the point in time SP1 the controller obtains two voltage samples including (1) the measured battery voltage V_{BAT1} and (2) the measured capacitor voltage V_{CT1}.

Since the voltage at the output of the DC/DC converter V_{DC} is known by design, and is stable assuming the DC/DC converter operates within its normal range, i.e. datasheet load current range, then at SP1 the moment of time T₂ the voltage on the capacitor V_{CT1} is known, the resistance of the current limiter R_{CL} is known, and the voltage V_{DC} applied to the input of the current limiter is known. There is now sufficient data at this point to calculate the current through the current limiter R_{CL} (I_{R}_{_{CL}}) using the following:

$${I}_{{R}_{C L}} = \frac{{V}_{D C} - {V}_{C T 1}}{{R}_{C L}} \qquad ( 1 )$$

This equation is the mathematical equivalent of a current-sense resistor (current to voltage transducer) and a unity-gain differential amplifier the use of which is traditional in current estimation.

Since the battery voltage V_{BAT1} is measured and V_{DC} is known at the same point in time, the real conversion coefficient K of the DC/DC converter can be estimated. The estimated value of K is dependent on the battery voltage and given by the following:

$$K = \frac{{V}_{B A T 1}}{{V}_{C T 1}} \qquad ( 2 )$$

In one embodiment, the measurement of battery and capacitor tank voltage samples is synchronous. According to the law of conservation of energy, the battery discharge current I_{BAT1} at SP1 (i.e. time T₂) can be calculated as follows:

$${I}_{B A T 1} = \frac{{I}_{{R}_{C L}}}{K} \qquad ( 3 )$$

Thus, at this point in time the real battery voltage V_{BAT1} and the calculated battery discharge current I_{BAT1} at moment of SP1 (time T₂) have been obtained. In one embodiment, the current limiter shunt switch is closed or I_{LIMIT2} is applied nearly immediately after a sample of the capacitor tank voltage is greater than or equal to the voltage threshold.

At time T=T₂, the current limiter is configured to permit a predetermined value I_{LIMIT2} creating a second current surge in the form of an almost instantaneous spike 146 in I_{BAT} to charge the capacitor tank to substantially the desired V_{OUT}. This forms the second current surge of the dual surge test. This is followed by an exponential (or linear or any physically implementable curve) decline 148 in I_{BAT} as the capacitor tank reaches full charge where the decline can be extremely rapid or extended in time. The decline in the battery discharge current is complete when the current reaches a level determined by the sum of the currents I_{BL} and capacitance tank self-discharge currents. Note that the second charging current surge which charges the capacitor tank to full charge occurs relatively quickly. Preferably, the measurement interval TMEAS is in the range of the expected duration of the second current surge which is not actually known. In one embodiment, the short time interval T_{MEAS} is used as an approximation of the unknown short interval. In an alternative embodiment, T_{MEAS} can be replaced by another time period T_{2NDSURGE}, without any change to the calculations described herein.

The battery discharge current may be maintained for some time until time T₃ to ‘calm’ transient chemical processes and restore normal operating voltage. This period of time is referred to as the battery relaxation period.

It is noted that the battery discharge current at the moment of the first charge current surge 141 and the subsequent decaying discharge current 142 are relatively small currents according to the design of the BPS circuit. In addition, it is assumed that the battery current load during the tail end of the time period between T₁ and T₂ corresponds to the constant current load from 0 to 20 milliseconds of the curve in FIG. 6. Therefore, the pair V_{BAT1}, I_{BAT1} of FIG. 7 is equivalent to the pair V₁, I₁ indicated in the circle 156 at SP1.

Very shortly after T₂, the shunt switch 96 closes, the capacitor tank, which is charged to V_{TH}<V_{DC}, is now directly connected to V_{DC} and a second current charging surge 146 occurs. This surge in current causes the battery voltage to drop. The second sampling point (SP2) of the dual surge test is preferably at the point of maximum drop in battery voltage (indicated by V_{BAT2} in FIG. 7). It is appreciated that it is known that the second charge current surge is relatively very short due to the output impedance of the DC/DC converter output being very low.

It is noted that the term “relatively very short” could mean a particular value, but for typical values of (1) capacitance (e.g., 4700 μF), (2) output impedance of the voltage converter (e.g., 10mΩ to 100mΩ), and (3) threshold voltage of about 92% of the voltage converter output, the term “relatively very short” means about 0.3 ms to 0.8 ms. Using Equation 4 below, the charge current surge is approximated with a flat current profile, when in reality it is a spike. To ensure comparability of the results of estimating and evaluating the internal resistance of many different batteries, the time duration T_{2NDSURGE} can be defined as a constant. For the “relatively very short” expected surge duration above, an approximate value of 1 ms for T_{2NDSURGE} is reasonable. In one embodiment, the T_{2NDSURGE} time duration value can be calibrated using the results of high-speed oscilloscopy of the battery discharge current.

Since (1) periodic measurements are taken with a known interval TMEAS specified by the particular implementation (e.g., kHz range making measurements approximately 1 ms apart), (2) the capacitance C of the capacitor tank is known, (3) the voltage V_{DC} to which the partially charged capacitor tank is charged is known, (4) the capacitor voltage V_{CT1} at moment of time SP1 (T₂) is known, and (5) the time interval T_{2NDSURGE} (i.e. measurement time period) is known and relatively very short, the charging current that is applied to the capacitor tank during time T_{2NDSURGE} to charge it to voltage V_{DC} can be estimated using the well-known equation for the instantaneous current through a capacitor:

$$i = C * \frac{dv}{dt} \qquad ( 4 )$$

Where i is the instantaneous current through the capacitor, C is the capacitance in Farads, and dv/dt is the instantaneous rate of change of voltage with respect to time. Applying the various values of FIG. 7 yields:

$${I}_{C T 2} = C * \frac{{V}_{D C} - {V}_{C T 1}}{{T}_{2 NDPULSE}} \qquad ( 5 )$$

Due to the fact that the capacitor tank is the sole significant load on both the voltage converter and the battery in this moment in time, the battery discharge current is mostly determined by the charging current into the capacitor tank. Using the real conversion coefficient K calculated supra in Equation 2, the second battery current spike amplitude I_{BAT2} is calculated using:

$${I}_{B A T 2} = \frac{{I}_{C T 2}}{K} \qquad ( 6 )$$

In addition, since any chemical battery can be represented by an inertial nonlinear system, its voltage drop from the second current surge can be measured either (1) after a fixed delay or (2) by detecting the minimum battery voltage some time after the second charge current surge (indicated by V_{BAT2} in FIG. 7). Regardless of the method of obtaining the voltage drop, at time SP2 the value of the battery voltage V_{BAT2} after the second discharge charge current surge is known.

At this point, since both pairs of voltages and currents at SP1 and SP2 are known, the internal resistance of the battery R_{BAT} can be estimated using the dual current surge method described supra as follows:

$${R}_{B A T} = \frac{{V}_{B A T 1} - {V}_{B A T 2}}{{I}_{B A T 2} - {I}_{B A T 1}} \qquad ( 7 )$$

Thus, determining internal battery resistance requires real measured values of battery voltage and calculated values of battery current at SP1 and SP2. In the battery power supply described supra, I_{BAT1} can be determined relatively precisely and I_{BAT2} less so. Since I_{BAT2} is preferably larger than I_{BAT1} for the dual current surge method described herein, Equation 7 can be rewritten as follows:

$${R}_{B A T} = \frac{{V}_{B A T 1} - {V}_{B A T 2}}{{I}_{BAT 2} * ϵ} \qquad ( 8 )$$

where ϵ represents a tolerable error. Assuming, ϵ is relatively constant, a scaled (e.g., 10 or 20%) time series of R_{BAT} can be calculated. In addition, considering that I_{BAT2} depends on 1/T_{2NDSURGE} which is also relatively constant, a scaled time series of battery resistance values can be determined.

In one embodiment, the capacitor current I_{CT2} given in Equation 5 can be considered to be a constant if the voltage threshold is relatively static and does not change dynamically. In this case, I_{BAT2} will still vary in a lifecycle of the BPS because K is not a constant. This is especially so considering batteries with non-flat discharge curves.

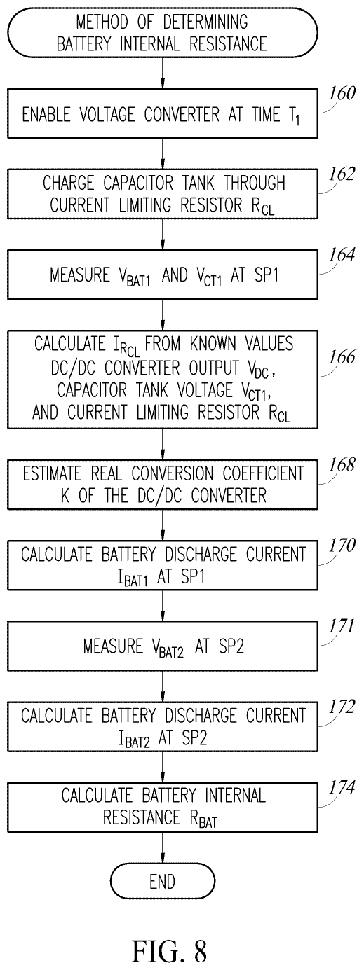

A flow diagram illustrating an example method for determining battery internal resistance is shown in FIG. 8. With reference also to FIGS. 2 and 7, the DC/DC converter which has been disabled or in sleep mode is enabled or woken up at time T₁ (step 160). The capacitor tank then begins charging through the current limiting resistor R_{CL} (step 162). At the first sample point SP1, the battery voltage V_{BAT1} and the voltage across the capacitor V_{CT1} are measured (step 164). The current through the current limiter resistor R_{CL} (I_{R}_{_{CL}}) can then be calculated from several known values including the DC/DC converter output voltage V_{DC}, the capacitor tank voltage V_{CT1}, and the battery voltage V_{BAT1} (step 166).

The actual conversion coefficient K of the DC/DC converter is then estimated using Equation 2 presented supra (step 168). Once K is calculated, the battery discharge current I_{BAT1} at SP1 can then be calculated (step 170). After the second surge in current which the BPS circuit applies once the capacitor tank voltage has reached the threshold voltage and at a second sampling point SP2, a second battery voltage measurement V_{BAT2} is taken and capacitor voltage V_{CT2} measurement is also taken (step 171) which enables the battery discharge current I_{BAT2} at SP2 to be calculated using Equation 5 above (step 172). At this point, both pairs of voltages and currents at SP1 and SP2 are known and the internal resistance of the battery R_{BAT} is estimated using Equation 6 above (step 174).

In this manner, the internal resistance of a battery connected to the BPS circuit can be periodically determined without requiring extra hardware and having minimal compute requirements.

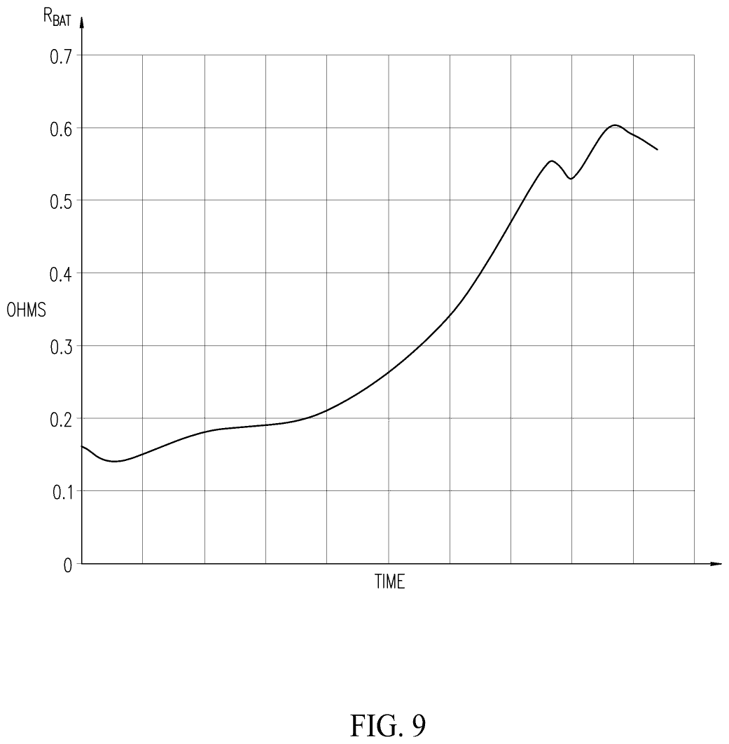

A high level block diagram illustrating an example application of the BPS of the present invention in a data logger is shown in FIG. 9. In one application, the BPS circuit and internal resistance estimation technique are used in a data logger device. As described supra, the BPS measures battery voltage at two times to create a double time series: (1) battery voltage before the second current surge (i.e. up to the voltage threshold) where the battery is under low current B_{LC}) and (2) minimum battery voltage during load operation after the relaxation period time until the load is turned off where the battery is under high current B_{HC}. During B_{HC}, the battery voltage is sampled at a frequency of about 1 kHz and minimum voltage points are searched.

These two time series reveal more about the specifics of the load operation than about the battery itself because information about the current consumed by the load is lacking. It is known, however, that this current can vary within very wide limits, e.g., from tens of milliamps to amperes, thus the load current having a wide dynamic range.

In one case, an abnormally large drop in B_{HC} could indicate that the load is consuming more current at that point in time and location than at other times and in other locations. If the load, for example, is a cellular modem, such anomalies indicate the state of the cellular channel, which cannot be controlled. It is possible, however, to conditionally determine “difficult” areas, the passage of which by the logger requires increased battery consumption, which allows for better prediction of the remaining operating time of the logger. Because the maximum current consumed at any moment in time by the load and the maximum battery drop (i.e. its minimum voltage) depend on unknown factors beyond control, the time series generated is not particularly valuable for assessing the state of the battery itself.

To distinguish the underlying causes of anomalies in B_{HC} another indicator that provides the battery status is needed that does not depend on external factors beyond control. Such an indicator is battery internal resistance which provides an indicator of the battery state of health (SoH). The common battery state of charge (SoC) indicator cannot be used for primary batteries because SoC is determined as the ratio of battery available capacity (C_{AVAILABLE}) to the manufacturer rated capacity (CRATED) when the battery is fresh, expressed as a percentage.

$${SoH}_{C} = ( \frac{{c}_{AVAILABLE}}{{c}_{RATED}} ) * 100 \% \qquad ( 9 )$$

In the case of primary (or pre-charged) batteries, the initial value of C_{AVAILABLE} is not fundamentally known. The BPS circuit, however, enables the evaluation of the internal resistance of the battery before the load is turned on, thus providing a third time series B_{IR} that does not require additional hardware and uses only firmware.

In one embodiment, a single battery internal resistance time series from a single device does not provide much value. It is much more valuable to have a group of many devices updating periodically where each device generates such a time series to a service hosted in the cloud. In this manner, the causes of anomalies can be reliably determined and it can be distinguished between what is caused by the battery and what is caused by the load operating conditions. This provides a reliable mechanism for identifying subpar battery suppliers, aids in planning purchases, and provides for more accurate use of information from the time series B_{LC} and B_{HC}.

There are additional uses for time series B_{LC}, B_{HC}, and B_{IR} that relate to the use of self-learning algorithms for detecting anomalies in time series and self-learning algorithms for predicting time series, which allow emergency situations to be recognized and the operating time of the device to be predicted with continuous improvement in the quality of prediction due to the constant replenishment of the time series database from the fleet of logging devices in the field.

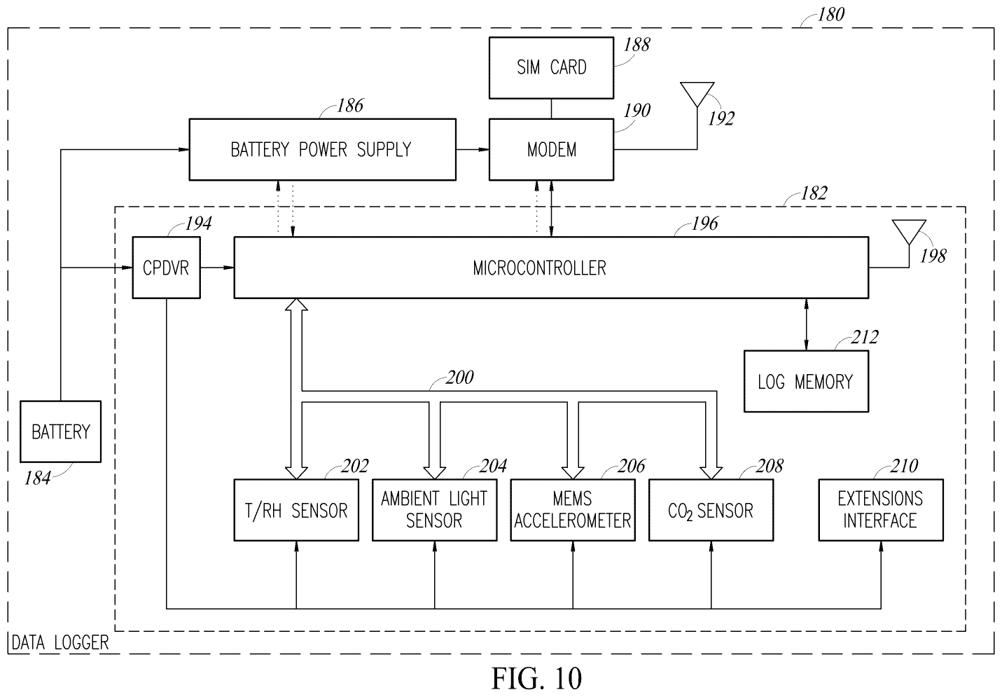

FIG. 10 is a block diagram illustrating an example application of the BPS circuit in a data logger device. The data logger, generally referenced 180, comprises a battery 184, BPS circuit 186 described in detail supra, SIM card 188, modem 190, cellular antenna 192, Bluetooth enabled microcontroller 196, Bluetooth antenna 198, constantly powered (always powered) domain voltage regulator (CPDVR) 194, system bus 200, temperature/relative humidity sensor 202, ambient light sensor 204, MEMS accelerometer 206, CO₂ sensor 208, extensions interface 210, and log memory 212.

In one embodiment, the data logger includes two separate powering voltage domains. Block 182 indicates an always powered domain that is powered by the CPDVR. Another domain is intermittently powered where the BPS circuit is used to power the modem and a SIM card which is powered by the modem for a short time. The modem may comprise any type of cellular modem including for example 3G, 4G, and 5G modems. All subsystems in all powering domains of the logger are controlled by the microcontroller which includes an integrated Bluetooth transceiver.

A sensor suite is within the always powered domain 182. In one embodiment, the T/RH sensor 202 is an open design as a hardware interface for extensions is used wherein each extension comprises a small PCB with electronics addons. The extensions have a standard for the programming interface used for them built into the system architecture, each implemented with its own microcontroller.

The log memory 212 functions to poll the sensors at a higher frequency compared to transmitting log data to one or more cloud servers via the modem which requires activation. In addition, since the availability of a cellular network cannot be guaranteed, any data exchange (or log delivery) session may fail. Therefore, the logger writes the log to the log memory, and frees this memory during successful sessions.

The various features and steps discussed above, as well as other known equivalents for each such feature or step, can be mixed and matched by one of ordinary skill in this art to perform methods in accordance with principles described herein. Although the disclosure has been provided in the context of certain embodiments and examples, it will be understood by those skilled in the art that the disclosure extends beyond the specifically described embodiments to other alternative embodiments and/or uses and obvious modifications and equivalents thereof. Accordingly, the disclosure is not intended to be limited by the specific disclosures of embodiments herein.

Any digital computer system, module and/or engine exemplified herein can be configured or otherwise programmed to implement a method disclosed herein, and to the extent that the system, module and/or engine is configured to implement such a method, it is within the scope and spirit of the disclosure. Once the system, module and/or engine are programmed to perform particular functions pursuant to computer readable and executable instructions from program software that implements a method disclosed herein, it in effect becomes a special purpose computer particular to embodiments of the method disclosed herein. The methods and/or processes disclosed herein may be implemented as a computer program product that may be tangibly embodied in an information carrier including, for example, in a non-transitory tangible computer-readable and/or non-transitory tangible machine-readable storage device. The computer program product may be directly loadable into an internal memory of a digital computer, comprising software code portions for performing the methods and/or processes as disclosed herein. The term “non-transitory” is used to exclude transitory, propagating signals, but to otherwise include any volatile or non-volatile computer memory technology suitable to the application. Additionally, or alternatively, the methods and/or processes disclosed herein may be implemented as a computer program that may be intangibly embodied by a computer readable signal medium. A computer readable signal medium may include a propagated data signal with computer readable program code embodied therein, for example, in baseband or as part of a carrier wave. Such a propagated signal may take any of a variety of forms, including, but not limited to, electro-magnetic, optical, or any suitable combination thereof. A computer readable signal medium may be any computer readable medium that is not a non-transitory computer or machine-readable storage device and that can communicate, propagate, or transport a program for use by or in connection with apparatuses, systems, platforms, methods, operations and/or processes discussed herein.

The terms “non-transitory computer-readable storage device” and “non-transitory machine-readable storage device” encompasses distribution media, intermediate storage media, execution memory of a computer, and any other medium or device capable of storing for later reading by a computer program implementing embodiments of a method disclosed herein. A computer program product can be deployed to be executed on one computer or on multiple computers at one site or distributed across multiple sites and interconnected by one or more communication networks.

These computer readable and executable instructions may be provided to a processor of a general purpose computer, special purpose computer, or other programmable data processing apparatus to produce a machine, such that the instructions, which execute via the processor of the computer or other programmable data processing apparatus, create means for implementing the functions/acts specified in the flowchart and/or block diagram block or blocks. These computer readable and executable program instructions may also be stored in a computer readable storage medium that can direct a computer, a programmable data processing apparatus, and/or other devices to function in a particular manner, such that the computer readable storage medium having instructions stored therein comprises an article of manufacture including instructions which implement aspects of the function/act specified in the flowchart and/or block diagram block or blocks.

The computer readable and executable instructions may also be loaded onto a computer, other programmable data processing apparatus, or other device to cause a series of operational steps to be performed on the computer, other programmable apparatus or other device to produce a computer implemented process, such that the instructions which execute on the computer, other programmable apparatus, or other device implement the functions/acts specified in the flowchart and/or block diagram block or blocks.

In the discussion, unless otherwise stated, adjectives such as “substantially” and “about” that modify a condition or relationship characteristic of a feature or features of an embodiment of the invention, are to be understood to mean that the condition or characteristic is defined to within tolerances that are acceptable for operation of the embodiment for an application for which it is intended.

Unless otherwise specified, the terms ‘about’ and/or ‘close’ with respect to a magnitude or a numerical value may imply to be within an inclusive range of −10% to +10% of the respective magnitude or value.

It should be noted that where an embodiment refers to a condition of “above a threshold”, this should not be construed as excluding an embodiment referring to a condition of “equal or above a threshold”. Analogously, where an embodiment refers to a condition “below a threshold”, this should not to be construed as excluding an embodiment referring to a condition “equal or below a threshold”. It is clear that should a condition be interpreted as being fulfilled if the value of a given parameter is above a threshold, then the same condition is considered as not being fulfilled if the value of the given parameter is equal or below the given threshold. Conversely, should a condition be interpreted as being fulfilled if the value of a given parameter is equal or above a threshold, then the same condition is considered as not being fulfilled if the value of the given parameter is below (and only below) the given threshold.

It should be understood that where the claims or specification refer to “a” or “an” element and/or feature, such reference is not to be construed as there being only one of that element. Hence, reference to “an element” or “at least one element” for instance may also encompass “one or more elements”.

As used herein the term “configuring” and/or “adapting” for an objective, or a variation thereof, implies using materials and/or components in a manner designed for and/or implemented and/or operable or operative to achieve the objective.

Unless otherwise stated or applicable, the use of the expression “and/or” between the last two members of a list of options for selection indicates that a selection of one or more of the listed options is appropriate and may be made, and may be used interchangeably with the expressions “at least one of the following”, “any one of the following” or “one or more of the following”, followed by a listing of the various options.

As used herein, the phrase “A,B,C, or any combination of the aforesaid” should be interpreted as meaning all of the following: (i) A or B or C or any combination of A, B, and C, (ii) at least one of A, B, and C, and (iii) A, and/or B and/or C. This concept is illustrated for three elements (i.e., A,B,C), but extends to fewer and greater numbers of elements (e.g., A, B, C, D, etc.).

It is noted that the terms “operable to” or “operative to” can encompass the meaning of the term “adapted or configured to”. In other words, a machine “operable to” or “operative to” perform a task can in some embodiments, embrace a mere capability (e.g., “adapted”) to perform the function and, in some other embodiments, a machine that is actually made (e.g., “configured”) to perform the function.

Throughout this application, various embodiments of this invention may be presented in a range format. It should be understood that the description in range format is merely for convenience and brevity and should not be construed as an inflexible limitation on the scope of the invention. Accordingly, the description of a range should be considered to have specifically disclosed all the possible subranges as well as individual numerical values within that range. For example, description of a range such as from 1 to 6 should be considered to have specifically disclosed subranges such as from 1 to 4, from 1 to 4, from 1 to 5, from 2 to 4, from 2 to 6, from 4 to 6 etc., as well as individual numbers within that range, for example, 1, 2, 3, 4, 5, and 6. This applies regardless of the breadth of the range.

Whenever a numerical range is indicated herein, it is meant to include any cited numeral (fractional or integral) within the indicated range. The phrases “ranging/ranges between” a first indicate number and a second indicate number and “ranging/ranges from” a first indicate number “to” a second indicate number are used herein interchangeably and are meant to include the first and second indicated numbers and all the fractional and integral numerals therebetween.

It should be appreciated that combination of features disclosed in different embodiments are also included within the scope of the present inventions.

While certain features of the invention have been illustrated and described herein, many modifications, substitutions, changes, and equivalents will now occur to those of ordinary skill in the art. It is, therefore, to be understood that the appended claims are intended to cover all such modifications and changes as fall within the true spirit of the invention.

What is claimed is:

1. A method of determining battery internal resistance for use in a power supply for providing battery based power to a load and that incorporates at least one current charging surge, comprising:
measuring a first battery voltage and a first capacitor tank voltage at a first sampling point in time before the current charging surge;
calculating a first battery discharge current based on said first battery voltage and said first capacitor tank voltage;
measuring a second battery voltage at a second sampling point in time after the current charging surge;
calculating a second battery discharge current based on said first capacitor tank voltage; and
estimating said battery internal resistance in accordance with said first battery voltage, said first battery discharge current, said second battery voltage, and said second battery discharge current.

2. The method according to claim 1, wherein battery and capacitor voltage are measured periodically in accordance with a controller programmed accordingly.

3. The method according to claim 1, wherein the first sampling point corresponds to a point in time in a current charging surge profile at which charging of said capacitor tank has reached a threshold voltage through a current limiter.

4. The method according to claim 1, wherein the second sampling point corresponds to a point in time in a current charging surge profile after which current limiting has been removed and said capacitor tank is charged to a desired output voltage.

5. The method according to claim 4, wherein a voltage converter coupled to said capacitor tank via said current limiting is operative to generate the desired output voltage.

6. The method according to claim 1, wherein the second sampling point corresponds to a point in time in a current charging surge profile where the battery voltage is at a minimum thus maximizing a difference between said first battery voltage and said second battery voltage.

7. The method according to claim 1, wherein the second sampling point corresponds to a relaxation/stabilization period in a current charging surge profile where said capacitor tank has been charged to a desired output voltage but before the load has been enabled.

8. A method of determining battery internal resistance for use in a power supply for providing battery based power to a load and that generates at least one current charging surge, comprising:
measuring a first battery voltage V_{BAT1} and a first capacitor tank voltage V_{CT1} at a first sampling point SP1 in time before the current charging surge;
calculating a first battery discharge current I_{BAT1} in accordance with
$${I}_{B A T 1} = \frac{{I}_{{R}_{C L}}}{K}$$
where K is a conversion coefficient of a voltage converter and given by
$$K = \frac{{V}_{B A T 1}}{{V}_{C T 1}}$$
and I_{R}_{_{CL}} is the current through a current limiter coupled to the output of the voltage converter and given by
$${I}_{{R}_{C L}} = \frac{{V}_{D C} - {V}_{C T 1}}{{R}_{C L}}$$
where V_{DC} is the output of the voltage converter and R_{CL} is the resistance of the current limiter;
measuring a second battery voltage V_{BAT2} at second sampling point SP2 in time after the current charging surge;
calculating a second capacitor discharge current I_{CT2} based on said first capacitor tank voltage V_{CT1} and V_{DC} in accordance with
$${I}_{CT 2} = C * \frac{{V}_{DC} - {V}_{CT 1}}{T}$$
where C is the capacitance of the capacitor tank, and T is a time interval;
calculating a second battery discharge current I_{BAT2} in accordance with
$${I}_{BAT 2} = \frac{{I}_{CT 2}}{K} ;$$
and
estimating said battery internal resistance R_{BAT} in accordance with
$${R}_{BAT} = \frac{{V}_{BAT 1} - {V}_{BAT 2}}{{I}_{BAT 2} - {I}_{BAT 1}} .$$

9. The method according to claim 8, wherein battery and capacitor voltage are measured periodically in accordance with a controller programmed accordingly.

10. The method according to claim 8, wherein the first sampling point corresponds to a point in time in a current charging surge profile at which charging of said capacitor tank has reached a threshold voltage through said current limiter.

11. The method according to claim 8, wherein the second sampling point corresponds to a point in time in a current charging surge profile after which current limiting has been removed and said capacitor tank has been charged to the desired output voltage.

12. The method according to claim 8, wherein the second sampling point corresponds to a point in time in a current charging surge profile where the battery voltage is at a minimum thus maximizing a difference between said first battery voltage and said second battery voltage.

13. The method according to claim 8, wherein the second sampling point corresponds to a relaxation/stabilization period in a current charging surge profile where said capacitor tank has been charged to the desired output voltage but before the load has been enabled.

14. A battery power supply (BPS) circuit for providing power to a load, comprising:
a voltage converter connected to a battery and operative to generate a desired output voltage;
a current limiter connected in series to said voltage converter and operative to limit the current output thereof,
a capacitor tank electrically connected to said current limiter and to the load;
a controller configured to generate at least one current charging surge and to estimate internal resistance of the battery by:
measuring a first battery voltage and a first capacitor tank voltage at a first sampling point in time before the current charging surge;
calculating a first battery discharge current based on said first battery voltage and said first capacitor tank voltage;
measuring a second battery voltage at a second sampling point in time after the current charging surge;
calculating a second battery discharge current based on said first capacitor tank voltage; and
estimating said battery internal resistance in accordance with said first battery voltage, said first battery discharge current, said second battery voltage, and said second battery discharge current.

15. The battery power supply circuit according to claim 14, wherein battery voltage and capacitor voltage are measured periodically by said controller.

16. The battery power supply circuit according to claim 14, wherein the first sampling point corresponds to a point in time in the current charging surge profile at which charging of said capacitor tank has reached a threshold voltage through a current limiter.

17. The battery power supply circuit according to claim 14, wherein the second sampling point corresponds to a point in time in the current charging surge profile after which current limiting has been removed and said capacitor tank has been charged to the desired output voltage.

18. The battery power supply circuit according to claim 14, wherein the second sampling point corresponds to a point in time in the current charging surge profile where the battery voltage is at a minimum thus maximizing a difference between said first battery voltage and said second battery voltage.

19. The battery power supply circuit according to claim 14, wherein the second sampling point corresponds to a relaxation/stabilization period in the current charging surge profile where said capacitor tank has been charged to the desired output voltage but before the load has been enabled.

20. A battery power supply (BPS) circuit for proving power to a load, comprising:
a voltage converter connected to a battery and operative to generate a desired output voltage;
a current limiter connected in series to said voltage converter and operative to limit the current output thereof,
a capacitor tank electrically connected to said current limiter and to the load;
a controller configured to generate at least one current charging surge and estimate internal resistance of the battery by:
measuring a first battery voltage V_{BAT1} and a first capacitor tank voltage V_{CT1} at a first sampling point SP1 in time before the current charging surge;
calculating a first battery discharge current I_{BAT1} in accordance with
$${I}_{BAT 1} = \frac{{I}_{{R}_{CL}}}{K}$$
where K is a conversion coefficient of a voltage converter and given by
$$K = \frac{{V}_{BAT 1}}{{V}_{CT 1}}$$
and I_{R}_{_{CL}} is the current through the current limiter and given by
$${I}_{{R}_{CL}} = \frac{{V}_{DC} - {V}_{CT 1}}{{R}_{CL}}$$
where V_{DC} is the output of the voltage converter, and R_{CL} is the resistance of the current limiter;
measuring a second battery voltage V_{BAT2} at a second sampling point SP2 in time after the current charging surge;
calculating a second capacitor discharge current I_{CT2} based on said first capacitor tank voltage V_{CT1} and V_{DC} in accordance with
$${I}_{CT 2} = C * \frac{{V}_{DC} - {V}_{CT 1}}{T}$$
where C is the capacitance of the capacitor tank, and T is a time interval; and
calculating a second battery discharge current I_{BAT2} in accordance with
$${I}_{BAT 2} = \frac{{I}_{CT 2}}{K} ;$$
and
estimating said battery internal resistance R_{BAT} in accordance with
$${R}_{BAT} = \frac{{V}_{BAT 1} - {V}_{BAT 2}}{{I}_{BAT 2} - {I}_{BAT 1}} .$$

21. The battery power supply circuit according to claim 20, wherein battery voltage and capacitor voltage are measured periodically by said controller.

22. The battery power supply circuit according to claim 20, wherein the first sampling point corresponds to a point in time in the current charging surge profile at which charging of said capacitor tank has reached a threshold voltage through said current limiter.

23. The battery power supply circuit according to claim 20, wherein the second sampling point corresponds to a point in time in the current charging surge profile after which current limiting has been removed and said capacitor tank has been charged to the desired output voltage.

24. The battery power supply circuit according to claim 20, wherein the second sampling point corresponds to a point in time in the current charging surge profile where the battery voltage is at a minimum thus maximizing a difference between said first battery voltage and said second battery voltage.

25. The battery power supply circuit according to claim 20, wherein the second sampling point corresponds to a relaxation/stabilization period in the current charging surge profile where said capacitor tank has been charged to the desired output voltage but before the load has been enabled.

26. An apparatus for determining battery internal resistance for use in a data logger, comprising:
a data logger including:
a plurality of sensors, each sensor generating sensor data;
a log memory for storing sensor data generated by each sensor;
a cellular modem for transmitting the sensor data to a cloud server;
a battery power supply (BPS) circuit coupled to a battery;
a first controller;
said battery power supply circuit generating at least one current charging surge and including a second controller operative to:
measure a first battery voltage and a first capacitor tank voltage at a first sampling point in time before the current charging surge;
calculate a first battery discharge current based on said first battery voltage and said first capacitor tank voltage;
measure a second battery voltage at a second sampling point in time after said current charging surge;
calculate a second battery discharge current based on said first capacitor tank voltage; and
estimate said battery internal resistance in accordance with said first battery voltage, said first battery discharge current, said second battery voltage, and said second battery discharge current.

27. An apparatus for determining battery internal resistance for use in a data logger, comprising:
a data logger including:
a plurality of sensors, each sensor generating sensor data;
a log memory for storing sensor data generated by each sensor;
a cellular modem for transmitting the sensor data to a cloud server;
a battery power supply (BPS) circuit coupled to a battery;
a first controller;
said battery power supply circuit generating at least one current charging surge and including a second controller operative to:
measure a first battery voltage V_{BAT1} and a first capacitor tank voltage V_{CT1} at a first sampling point SP1 in time before the current charging surge;
calculate a first battery discharge current I_{BAT1} in accordance with
$${I}_{BAT 1} = \frac{{I}_{{R}_{CL}}}{K}$$
where K is a conversion coefficient of a voltage converter and given by
$$K = \frac{{V}_{BAT 1}}{{V}_{CT 1}}$$
and I_{R}_{_{CL}} is the current through a current limiter coupled to the output of the voltage converter and given by
$${I}_{{R}_{CL}} = \frac{{V}_{DC} - {V}_{CT 1}}{{R}_{CL}}$$
where V_{DC} is the output of the voltage converter and R_{CL} is the resistance of the current limiter;
measure a second battery voltage V_{BAT2} at second sampling point SP2 in time after the current charging surge;
calculate a second capacitor discharge current I_{CT2} based on said first capacitor tank voltage V_{CT1} and V_{DC} in accordance with
$${I}_{CT 2} = C * \frac{{V}_{DC} - {V}_{CT 1}}{T}$$
where C is the capacitance of the capacitor tank, and T is a time interval;
calculate a second battery discharge current I_{BAT2} in accordance with
$${I}_{BAT 2} = \frac{{I}_{CT 2}}{K} ;$$
and
estimate said battery internal resistance R_{BAT} in accordance with
$${R}_{BAT} = \frac{{V}_{BAT 1} - {V}_{BAT 2}}{{I}_{BAT 2} - {I}_{BAT 1}} .$$
